(19) United States
(12) Patent Application Publication
(10) Pub. No.: US 2008/0265920 A1
(43) Pub. Date: Oct. 30, 2008

(54) PROBE CARD

(75) Inventor: Ki Don Ko, Gyeonggi-do (KR)

Correspondence Address: PEARNE & GORDON LLP, 1801 EAST 9TH STREET, SUITE 1200, CLEVELAND, OH, 44114-3108, US

(73) Assignee: WILLTECHNOLOGY CO., LTD., Gyeonggi-do (KR)

(21) Appl. No.: 12/102,192

(22) Filed: Apr. 14, 2008

(30) Foreign Application Priority Data
Apr. 25, 2007 (KR) 10-2007-0040209

(51) Int. Cl. G01R 31/28

(52) U.S. Cl. 324/754

(57) ABSTRACT

Disclosed is a probe card providing an upper structure formed to be separatable from a lower structure and a lower structure including a lower substrate electrically connected with a plurality of the needles and a plurality of the lower terminals independently connected with the needles formed above the lower substrate. In particular, the lower structure of the probe card includes a needle fixing structure, a plurality of the needles fixed on the needle fixing structure, a lower substrate provided on the needle fixing structure while electrically connecting with the needles, and a plurality of the lower terminals formed on the upper surface of the lower substrate in order to be independently connected with the each needle. Meanwhile, the upper structure separatable from the lower structure includes a main substrate and a plurality of the upper terminals formed on the lower surface corresponding to the lower terminals.

### FIELD OF THE INVENTION

The present disclosure relates to a probe card, more particularly, a probe card that is provided with separatable needles, thereby providing the easiness of maintaining and repairing while improving the workability and productivity.

### BACKGROUND OF THE INVENTION

Generally, a semiconductor device is manufactured through a fabrication process forming a pattern on a wafer and an assembly process assembling the patterned wafer into each individual chip.

Between the fabrication process and the assembly process, there is a process called electrical die sorting (EDS) which tests electrical characteristics of each chip constituting the wafer. As a process to detect defective chips in the wafer, the EDS process generally uses a testing apparatus which determines defects by applying an electrical signal to the chips constituting the wafer and checking a signal returned in response.

The electrical test is generally performed by a testing apparatus called probe card. The probe card includes a plurality of needles which apply electrical signals to a contacted pattern of a chip. More particularly, the electrical characteristics test of a semiconductor wafer normally measures electrical characteristics by applying a specific current through the needles when the needles of the probe card are contacted with electrode pads or circuit terminals of the semiconductor wafer.

If a result of the test using the probe card is determined to be fair, the semiconductor device is completed through an afterward assembly process such as a packaging and the like.

FIG. 1 is a cross-sectional view illustrating the structure of a conventional probe card.

As illustrated in FIG. 1, the conventional probe card 20 includes a main substrate 30 on which a probe circuit pattern is formed and a plurality of needles 50 mounted under the main substrate 30 for vertically contacting to a plurality of electrode pads (or circuit terminals) exists on a test object, a wafer 10. Besides, each of the needles 50 is supported and fixed by a needle fixing block 40 fixedly installed on a lower surface of the main substrate 30 while electrically connecting to the main substrate 30.

The needle fixing block 40 includes a connection plate 42 disposed apart from the lower surface of the main substrate 30 by a predetermined distance and a tip plate 44 disposed apart from a lower side of the connection plate 42. Each of the plates 42 and 44 is disposed in parallel to the main substrate 30, and the disposition can be maintained by fastening members 45 which penetrate through the plates 42 and 44 while fixing to the main substrate 30.

Each of the needles 50 is disposed between the connection plate 42 and the tip plate 44. One end of the needle 50 passing through the connection plate 42 and is electrically connected to a probe circuit pattern of the main substrate 30 through a wire 32 by soldering. The other end of the needle 50 passing through the tip plate 44 is projected to the outside to be contacted with the test object. In the plates 42, 44 and the main substrate 30, the guide holes 42a, 44a and 31, which allow the needles 50 passing through, are formed on a same line respectively. Furthermore, the disposition of the needles 50 is constituted to be fixed by a resin (epoxy or the like) layer 46 formed on an upper surface of the connection plate 42.

Moreover, in a space between the connection plate 42 and the tip plate 44, a middle portion of the each needle 50 is formed with a bending portion 52 which is bent in prescribed diameter for elastic flow. By the bending portion 52, each needle can be elastically contacted to the test object.

However, in the conventional probe card 20, a disposition of the needles 50 is maintained and fixed by a separate resin layer 46 formed on the upper surface of the connection plate 42. Thus, the number of components and manufacturing steps are increased, and accordingly manufacturing cost is increased while the workability and productivity are decreased.

Further, the conventional probe card 20 has a problem requiring the separate resin layer 46 to be formed on the upper surface of the connection plate 42 for maintaining and fixing the disposition of the needle 50. Also, before the resin layer 46 is formed, a fixing unit such as separate jigs was required for temporarily fixing the needle 50 disposed on the needle fixing block 40.

Meanwhile, a number of needles are needed for examining a test object such as a semiconductor wafer, which contains a number of pads to be contacted. As a load is applied repeatedly during the testing process, these needles can be deformed by stresses or become unusable by abrasion. In order to prevent a case that the expensive probe card become usable due to deformed or abraded needles among a number of needles, the deformed or abraded needles should be easily replaceable.

However, the needles 50 of the conventional probe card 20 are fixedly maintained by the resin layer 46 formed on the upper surface of the connection plate 42, and the upper end of the each needle is connected to the wire 32, which is electrically connected to the probe circuit pattern of the main substrate 30, by soldering. Therefore, its maintenance and repair are very difficult.

Furthermore, in order to replace the deformed or abraded needles in the conventional probe card 20, not only the connection made by soldering the deformed or abraded needles with the wires 32 should be released, but also the connection between normal needles and the wires 32 should be released. After that, the resin layer 46 is removed and the deformed or abraded needles are replaced. As mentioned above, for the conventional probe card 20, a number of normal needles are required to go through a repairing process as well because of some failed needles. Consequently, much manpower and time are consumed for the maintenance and repair, and related costs are increased.

### BRIEF SUMMARY OF THE INVENTION

In view of the foregoing, the present disclosure has been made to solve the above-mentioned problems occurring in the prior art, and an object of the present disclosure is to provide a probe card including a lower structure having a needle fixing structure, a plurality of needles fixed on the needle fixing structure, a lower substrate provided above the needles fixing structure and electrically connected with the needles, and a plurality of lower terminals formed on an upper surface in order to independently connect the lower substrate with each needle; and an upper structure connected to the lower structure while separatable from the lower structure and including a main substrate and a plurality of an upper terminals which are formed on the lower surface of the main substrate in correspondence to each lower terminal.

Also, the present disclosure can test chips (wafers and the like) with divided detecting cell units and provides a probe card that includes a lower structure having a plurality of the divided detecting cell and an upper structure separatable from the lower structure, wherein each detecting cell having a needle fixing structure, a plurality of needles fixed on the needle fixing structure, the lower substrate provided on the needle fixing structure and electrically connected with the needles, and a plurality of the lower terminals formed on the lower substrate thereby electrically connecting with each needle and the upper structure includes a main substrate and a plurality of upper terminals which are formed on the lower surface of the main substrate in correspondence to the lower terminal thereby electrically connecting the needles with the main substrate.

At this point, the lower structure can be divided in to the block units, on which a plurality of the lower substrates divided into the divided detecting cell units can be installed. In case that a detecting cell unit of the lower structure is defective, the defected detecting cell unit and the needles of the lower structure can be separated and then replaced or repaired. So, by simply replacing a part of the detecting cell, repair or replacement can be facilitated.

### BRIEF DESCRIPTION OF THE DRAWINGS

The disclosure may best be understood by reference to the following description taken in conjunction with the following figures:

FIG. 1 is a cross-sectional view illustrating a structure of a probe card in accordance with a conventional probe card;

FIG. 2 is a cross-sectional view illustrating a structure of a probe card in accordance with a first embodiment of the present invention;

FIGS. 3 and 4 are enlarged cross-sectional views of A section in FIG. 2;

FIG. 5 is a cross-sectional view illustrating a probe card in accordance with a second embodiment of the present invention;

FIG. 6 is a perspective view illustrating a lower structure of the probe card in a block; and

FIGS. 7 and 8 are enlarged cross-sectional views illustrating the probe card including detecting cell in accordance with the second embodiment of the present invention.

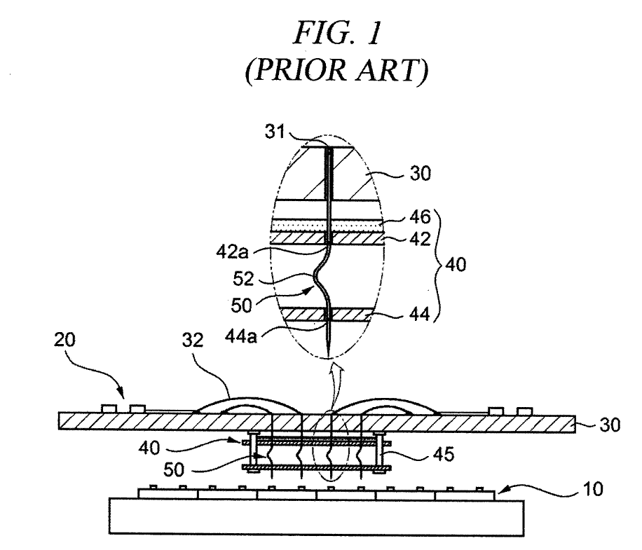

### DETAILED DESCRIPTION OF THE INVENTION

Hereinafter, embodiments of the present invention will be described in detail with reference to the accompanying drawings so that the present invention may be readily implemented by those skilled in the art. However, it is to be noted that the present invention is not limited to the embodiments but can be realized in various other ways. In the drawings, parts irrelevant to the description are omitted for the simplicity of explanation, and like reference numerals denote like parts through the whole document.

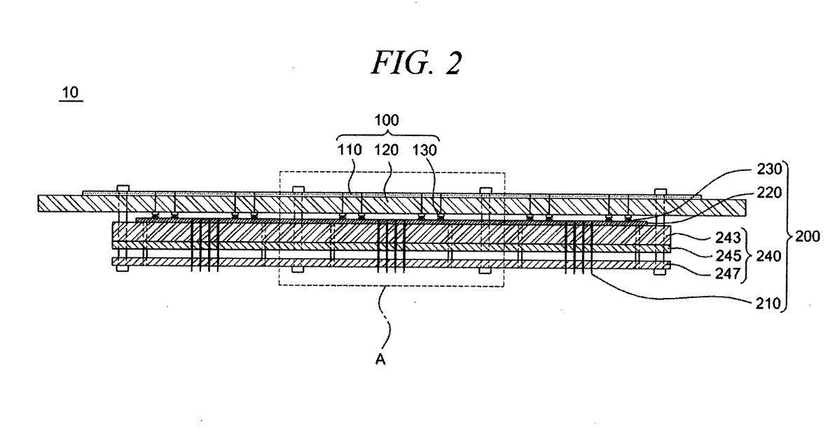

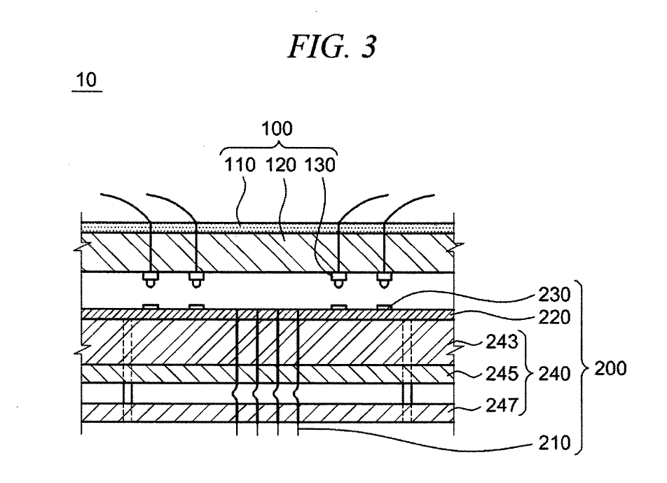

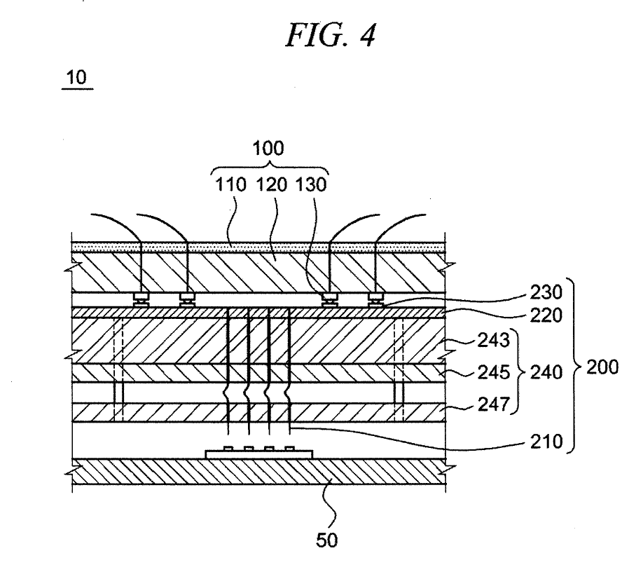

FIG. 2 is a cross-sectional view illustrating a structure of a probe card in accordance with a first embodiment of the present disclosure, and FIGS. 3 and 4 are enlarged cross-sectional views of A section in FIG. 2.

As shown in FIGS. 2 to 4, the probe card in accordance with the first embodiment can be separated into a lower structure 200 and an upper structure 100. The lower structure 200 can include a needle fixing structure 240; a plurality of needles 210 to be fixed on the needle fixing structure 240; and a lower substrate 220 which is provided above the needle fixing structure 240 and electrically connected with the needles 210. At the same time, the lower substrate 220 can include a plurality of lower terminals 230 which are formed on the upper surface of the lower substrate 220 to connect each needle 210 independently. Also, the upper structure 100 can include a main printed-circuit board 110; a main substrate 120; and a plurality of an upper terminal 130 which is formed below the main substrate 120 in correspondence to each lower terminal 230. The upper terminal 130 can be formed to be separatable from the lower structure 200.

Here, the needle fixing structure 240 can be formed with a reinforced fixing plate 243, an upper fixing plate 245, and a lower fixing plate 247. The needle 210 is extended over a lower portion of the lower fixing plate 247 and projected to the exterior. Further, an upper portion of the needle 210 can be fixedly supported among the reinforced fixing plate 243, the upper fixing plate 245, and the lower fixing plate 247 through which the needle can be projected to electrically contact with the wafer 10.

The lower substrate 220 can be provided at upper portion of the reinforced fixing plate 243, and the lower terminal 230 can be provided at the upper surface of the lower substrate 220. The lower terminal 230 can be formed in 1-on-1 correspondence to needle 210, which can be electrically connected with the lower terminal 230 through a pattern formed on the lower substrate 220. The lower terminal 230 connected with the needle 210 can be connected with the upper structure 100 when the lower terminal 230 is contacted with the upper terminal 130, which will be explained later.

Further, the lower terminal 230 can be formed near the needle 210 which is formed on the lower substrate 220. A formation of the lower terminals 230 can be provided in various formations formed in 1-on-1 correspondence to the needles 210, and the present disclosure is not limited or restricted to the formation of the lower terminals 230.

Further, the upper terminals 130, which can be connected with each lower terminal 230, can be provided on the lower surface of the main substrate 120, and the upper structure 100 including a main printed-circuit board 110 can be formed on the upper surface of the upper surface of the main substrate 120. Here, the upper terminal 130 can be formed in 1-on-1 correspondence to the lower terminal 230 and can also include a connecting electrode that can be connected with the main printed-circuit board formed on the upper portion of the upper terminal 130. Also, the upper structure 100 provided with the upper terminal 130 and the lower structure 200 provided with the lower terminal 230 can be formed to be separatable from each other. In addition, at least one of the upper terminal 130 and the lower terminal 230 can be formed as an elastic electrode, and they can be provided in various forms that can electrically connect the upper structure 100 with the lower structure 200. As an example, the upper terminal 130 can be formed as a pogo pin type. The needle 210 can perform probing motion when the upper terminal 130 and the lower terminal 230 are contacted.

The main substrate 120 has a disk-like shape, and a probe circuit pattern (not shown) can be formed on the upper surface of the main substrate 120. This main substrate 120 can be installed on a test head where a computer and a tester are connected. Also, as explained earlier, the upper structure 100 can be formed as a structure separatable from the lower structure 200. Due to this separatable structure, replacement or repair can be facilitated on damaged or deformed needle 210. Specifically, in case that the needle 210 of the lower structure 200 needs a replacement or repair due to a deformation or damage, the lower structure 200 can be exchanged simply since the needle is not fixed to the upper structure 100 but separatable. Therefore, workability and productivity needed for replacement and repair can be improved.

In accordance with the first embodiment, one lower substrate 220 is attached on the lower structure 200. However, the lower substrate can be divided into a plurality of units and installed on the lower structure 200. On each lower substrate 220, vertical needles for testing chips can be installed. Here, the lower substrate 220 can corresponds to at least one chip unit so that it can be used for connecting the chips with the main substrate 120. Preferably, each of the lower substrates 220 corresponds to each of the chips such that the lower substrate 220 can be exchanged on the basis of chip unit.

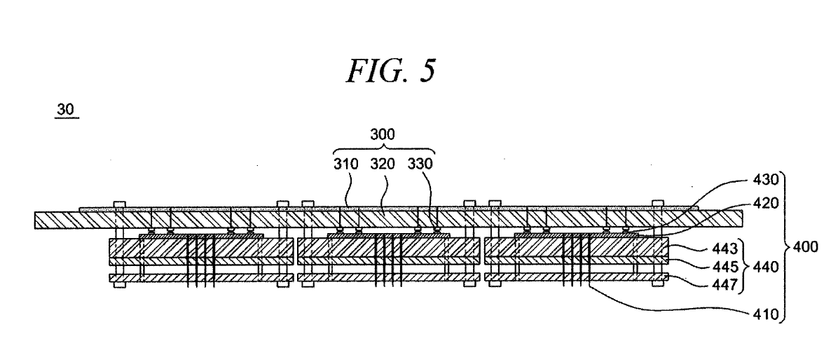

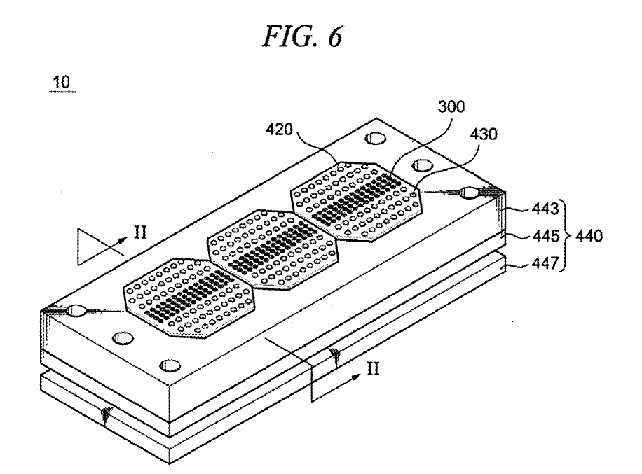

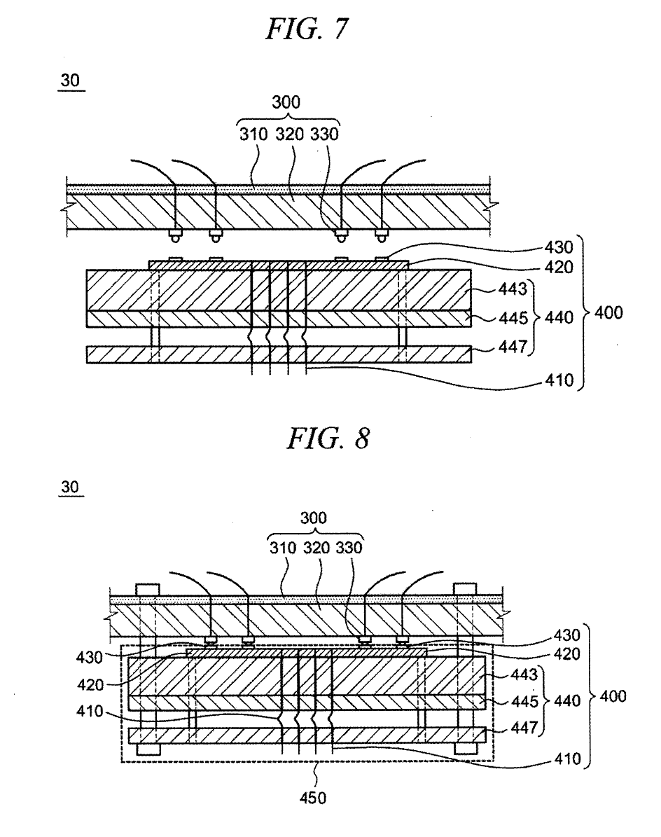

FIG. 5 is a cross-sectional view illustrating a probe card in accordance with a second embodiment of the present invention; FIG. 6 is a perspective view illustrating the lower structure of the probe card; and FIGS. 7 and 8 are enlarged cross-sectional views illustrating probe card including detecting cell in accordance with the second embodiment of the present invention. In addition, for the previously mentioned same or similarly corresponding part, a same or similarly corresponding reference number is given, omitting a detailed explanation.

As illustrated in FIGS. 6 to 8, in accordance with the second embodiment of the present invention, the probe card 30 includes a lower structure 400 having a plurality of the detecting cell 450; and an upper structure 300 separatable from the lower structure 400. Different from the first embodiment, the lower structure 400 has a plurality of the separate detecting cell 450. Each of the detecting cells 450 contains the needle fixing structure 440, a plurality of the needles 410 fixed on the needle fixing structure 440, the lower substrate 420 provided on the needle fixing structure 440 and electrically connected with the needles 410, and a plurality of lower terminals formed on the lower substrate 420 thereby electrically connecting with each needles.

On the upper surface of the lower structure 400, the main printed-circuit board 310; the main substrate 320; and the upper structure 300, which includes a plurality of the upper terminals 330 formed in correspondence to each lower terminal 430 under the main substrate 320, can be provided.

The lower structure 400 can be divided into the detecting cell 450, thereby performing probing motion, and each divided detecting cell 450 can include a sub printed-circuit board.

The separatable detecting cell 450 can facilitate the maintenance and repair of the probe card 30.

Further, the lower terminal 430 can be formed in 1-on-1 correspondence with the needles 410, which can be electrically connected with the lower terminal 430 through the pattern formed on the lower substrate 420. Also, on the upper surface of the lower terminal 430, the electrically connectable upper terminal 330 can be provided. For the lower structure 400 provided with the lower terminal 430 and the upper structure 300 provided with the upper terminal 330, each can be formed as a separatable structure. Additionally, the probe card, in accordance with the second embodiment, does not use a separate wire for electrically connecting the upper terminal 330 with the lower terminal 430, but the wire or the like can be used depending on a situation.

The lower structure 400 and the upper structure 300 are separatable, and the detecting cell 450 can be separated from the lower structure 400. Thus, in case of malfunction occurred during probing motion, simply the detecting cell 450 of the lower structure 400 can be replaced or repaired. In other words, for the conventional probe cards, a main substrate as a whole had to be repaired or replaced when a needle is broken. In such a case, because usable needles can also be exchanged or repaired, time or manpower can be wasted for maintaining and repairing the probe card, and further, the repair costs can be increased. However, according to the present invention, the time, the manpower, and the costs for maintaining and repairing the probe card 30 can be saved by replacing or repairing simply the needles that needs a replace or repair as the separatable detecting cell 450 is separated from the lower structure 400.

According to the present invention, by dividing the probe card as an upper structure and a lower structure, the probe card can be formed as a separatable and connectable structure. That is, when a needle is broken, the separation between the lower structure and the upper structure allows replacement or repair simply on the lower structure, thereby saving the time and the manpower needed for maintaining and repairing the probe card. Besides, the lower substrate of the lower structure can be formed in the detecting cell unit, which can be formed to be separatable. In other words, since the detecting cell can be separated from the lower structure, the costs needed for maintenance and repair can be saved by simply repairing or replacing the part that need a repair or a replace. Further, the time and the manpower needed for maintaining and repairing the probe card can be saved as well.

The above description of the present disclosure is provided for the purpose of illustration, and it would be understood by those skilled in the art that various changes and modifications may be made without changing technical conception and essential features of the present disclosure. Thus, it is clear that the above-described embodiments are illustrative in all aspects and do not limit the present disclosure.

The scope of the present disclosure is defined by the following claims rather than by the detailed description of the embodiment. It shall be understood that all modifications and embodiments conceived from the meaning and scope of the claims and their equivalents are included in the scope of the present disclosure.

What is claimed is:

1. A probe card comprising:
a lower structure including a needle fixing structure, a plurality of needle fixed on the needle fixing structure, a lower substrate provided above the needle fixing structure and electrically connected with needles, and a plurality of lower terminals formed on an upper surface in order to independently connect the lower substrate with each needle; and
an upper structure, connected to the lower structure while separatable from the lower structure, including a main substrate and a plurality of an upper terminals which are formed on the lower surface of the main substrate in correspondence to each lower terminal.

2. The probe card of claim 1, wherein the lower terminals are formed around an upper portion of the needle in correspondence to the needles.

3. The probe card of claim 2, wherein the lower terminals are formed on the upper surface of the lower substrate, and each needle is 1-on-1 connected with the lower terminals through a pattern formed on the lower substrate.

4. The probe card of claim 1, wherein at least one of the upper terminal and the lower terminal is formed as an elastic electrode form.

5. The probe card of claim 4, wherein the upper terminals are 1-on-1 connected with the lower terminals.

6. The probe card of claim 1, wherein the lower structure is formed to be separatable from the upper structure.

7. The probe card of claim 1, wherein a plurality of the lower substrates is installed on the lower structure and the lower substrate is defined in a predetermined testing unit.

8. A probe card comprising:
a lower structure including a plurality of the divided detecting cell; and
an upper structure separatable from the lower structure,
wherein each detecting cell has a needle fixing structure, a plurality of needles fixed on the needle fixing structure, the lower substrate provided on the needle fixing structure and electrically connected with the needles, and a plurality of lower terminals formed on the lower substrate thereby electrically connecting with each needle; and
the upper structure includes a main substrate and a plurality of upper terminals which are formed on the lower surface of the main substrate in correspondence to the lower terminal thereby electrically connecting the needles with the main substrate.

9. The probe card of claim 8, wherein the detecting cell is formed to be separatable from the lower structure.

10. The probe card of claim 9, wherein the lower terminals are formed on the upper surface of the lower substrate and the each needle is 1-on-1 connected to the lower terminal.

11. The probe card of claim 8, wherein the lower substrate is a printed-circuit board.
